(19) United States
(12) Patent Application Publication
(10) Pub. No.: US 2015/0104595 A1
(43) Pub. Date: Apr. 16, 2015

(54) PERFORATED PROTECTIVE FILM FOR ELECTRONIC DEVICES

(71) Applicant: Matthew B. Parrill, Winchester, VA (US)

(72) Inventor: Matthew B. Parrill, Winchester, VA (US)

(21) Appl. No.: 14/050,822

(22) Filed: Oct. 10, 2013

(51) Int. Cl. H05K 5/02

(52) U.S. Cl. CPC H05K 5/02
USPC 428/36.5; 521/50

(57) ABSTRACT

A protective film for an electronic device is described. The protective film includes a film operable to cover at least a portion of the electronic device, and a plurality of pores directly manufactured in, or cut in the film in locations where sound passes into or out of the electronic device, the pores adapted to allow sound transmission while limiting liquid ingress.

### BACKGROUND

1. Field

The present invention relates to protective films and, more particularly, to a perforated film membrane for an electronic device that provides protection from the elements, such as scratches, liquids and particulates.

2. Related Art

Protective films, or touchscreen membranes, for electronic devices, such as such as desktop computers, notebook computers, personal digital assistants, cell phones, smart phones, navigation devices, portable game systems, and mobile media devices, are typically cut to shape and applied to a device surface or mounted in an enclosure. These membranes may be a contiguous and unbroken surface, or include die cut openings in the planar surface that remove the obstructing film from the areas of acoustic transducers such as microphones and speakers. These openings allow the transmission of sound, but also create points of entry for liquids that may damage the internal electronics. Alternately, the openings may be covered by an additional water-resistant acoustical vent material thereby adding an assembly requirement.

Some current protective films are designed to protect devices primarily from scratches. These protective films do not offer protection from liquid entering openings that have been created for the transmission of sound. Other solid membranes act as a component of a sealed enclosure, but restrict sound transmission through varying degrees of acoustic impedance.

As can be seen, there is a need for an improved protective film that can protect an electronic device from liquid ingress while allowing the transmission of sound for microphone and speaker use without requiring additional components such as acoustical vents. The polymerics employed in these applications may be hydrophobic, oleophobic, or treated to assume those qualities as required by the application.

### SUMMARY

An example embodiment is directed to a protective film for an electronic device. The protective film includes a film operable to cover at least a portion of the electronic device, and a plurality of pores directly manufactured in, or cut in the film in locations where sound passes into or out of the electronic device, the pores adapted to allow sound transmission while limiting liquid ingress.

Another example embodiment is directed to a case for an electronic device. The case includes a device housing, a film membrane attached to the device housing and operable to cover at least a portion of the electronic device, and a plurality of pores directly manufactured in, or cut in the film membrane in locations where sound passes into or out of the electronic device, the pores adapted to allow sound transmission while limiting liquid ingress.

### BRIEF DESCRIPTION OF THE DRAWINGS

FIG. 1 is a perspective view of a perforated device film adapted to fit over a front face of an electronic device according to an example embodiment.

FIG. 2 is a perspective view of a perforated device film having side surfaces according to another exemplary embodiment.

FIG. 3 is a perspective view of a perforated device film incorporated into a frame or case for an electronic device, according to another exemplary embodiment.

FIG. 4 is a photograph of a magnified protective film to illustrate the pores therein.

### DETAILED DESCRIPTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides a protective polymeric film membrane that can protect a device screen from scratches, and the like. The protective film of the present invention includes micro-perforations in the film, referred to hereafter as pores or a pore array, to allow sound transmission for microphone and speaker openings, while providing protection for these openings from the elements, such as from liquids. Conventional protective films include die cut openings for the microphone and/or speaker, allowing water to penetrate these openings. The pores in the protective film of the present invention allow the transmission of sound, but do not allow the passage of contaminants, dust or low pressure liquid. Accordingly, the pores provide for low acoustic impedance while restricting liquid ingress.

The protective film of the present invention can be used on various electronic devices in various fields where a device may need protection from the ingress of liquid, but must maintain the ability to transmit or receive sound. The electronic device could include desktop computers, notebook computers, personal digital assistants, cell phones, smart phones, navigation devices, portable game systems, kiosks, control pads, vehicles of all types, and other communications or mobile media devices and the like.

The protective film of the present invention can be made of a single layer, or multiple layers of suitable polymeric material, or the like. The pores can be disposed through the film in the areas where sound transmission is desired, such as over speaker and microphone openings. The pores can be, for example, 1 to 1000 micrometers in diameter. In another example, the pore diameter is less than 150 micrometers. The pore diameter and interpore spacing between pores may be adjusted to provide the lowest acoustic impedance, optimal ingress protection, or a balanced density. The open area percentage, which can be understood as the open pore area divided by the total sample area in percentage terms, can be configured to allow sound transmission with minimal or no loss in quality while still retaining waterproof features. The thickness of the protective film itself can be tailored to the application and may be in a range of one to fifty thousandths of an inch (0.001″ to 0.050″), in one example.

The protective film may be directly manufactured with these pores in specific locations, or throughout, by mechanical or chemical processes. The pores may also be cut in the protective film substrate by means known in the art, such as with a CO₂ laser, femtosecond laser, other optical devices, water jets, chemical reaction, or a mechanical device. Pores, or arrays of pores, may be created individually, in sets, or in a singular event using a masking device to define a pore or an array of pores.

The polymeric film can be die cut in device-specific shapes. The device-touching surfaces can attach statically, include a layer of adhesive to allow the end user to apply the film to their electronic device as is known, or by any other means of permanent, semi-permanent, or temporary attachment.

The polymeric film can include areas to accommodate volume buttons, slide switches, ports and the like. For example, a control surface can be formed in the substrate material comprising the polymeric film or a separate material can be disposed in this area by insert-mold, over-mold, or alternate means to accommodate the use of buttons, where this separate material may be more resistant to wear, breaking or cracking, even with repeated use as is often the case with buttons. A sealable flap, or flaps, may be formed in the polymeric film to removably seal openings for areas such as charging ports, headphone ports, or other connections.

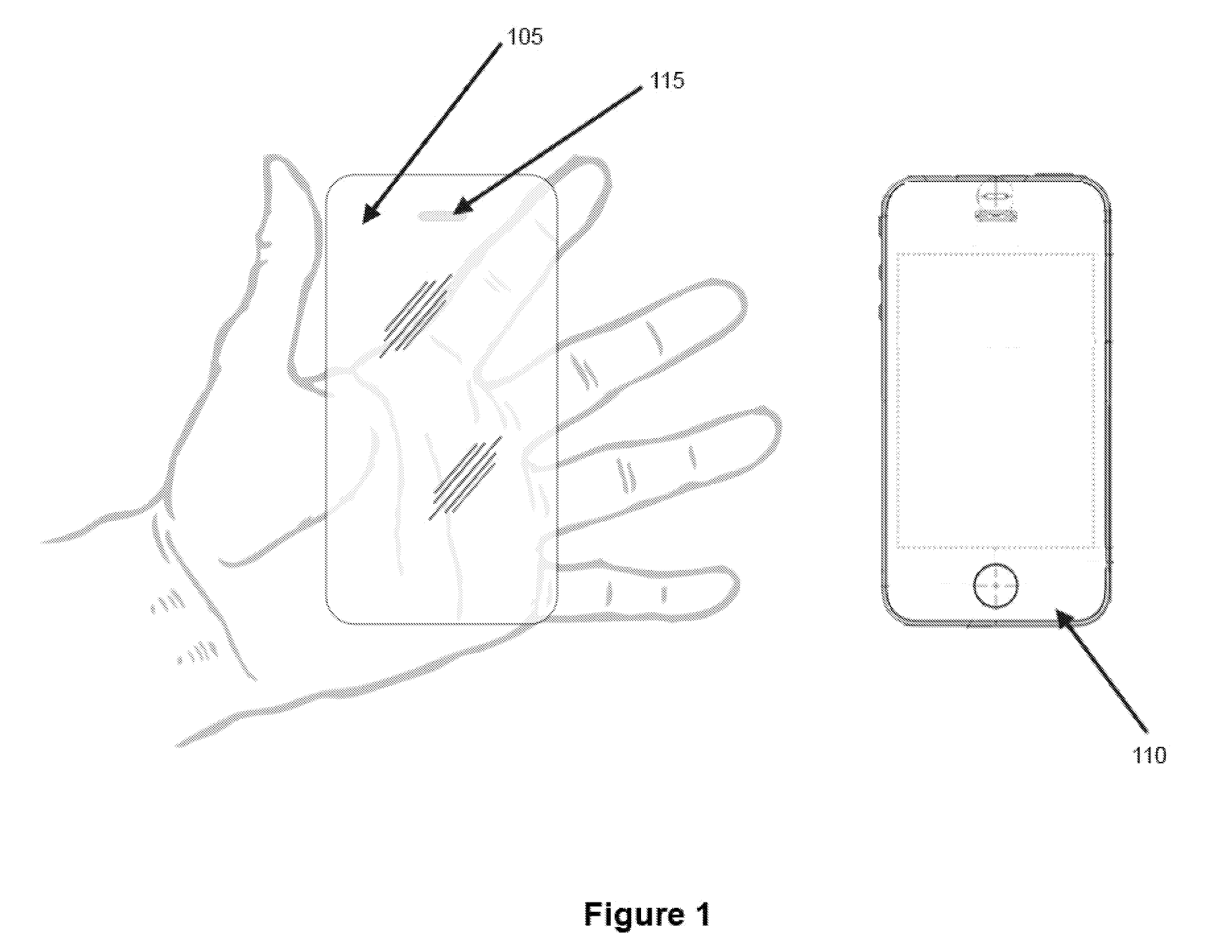

Referring to FIG. 1, in one embodiment of the present invention, a polymeric film 105 can be designed to fit over a front face of an electronic device 110. The polymeric film can include pores (indicated as a pore array 115) formed therethrough to allow sound transmission to and from speakers and microphones.

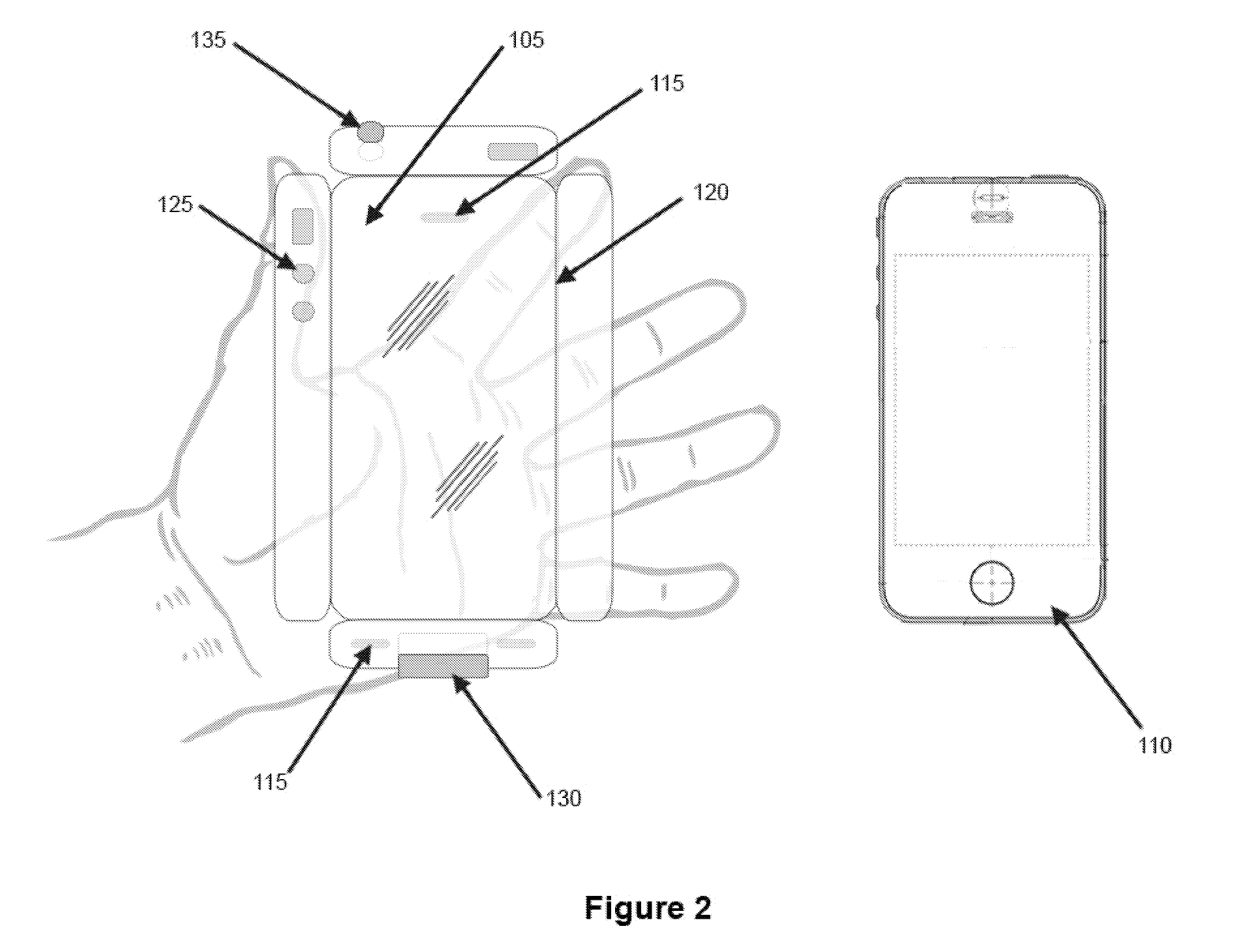

Referring to FIG. 2, in another embodiment of the present invention, the polymeric film can be made up of multiple parts, or sized to wrap around multiple sides of the electronic device. Bends 120 may be pre-formed in the film to allow the film to easily conform to the shape of the electronic device. Similar to the embodiment of FIG. 1, pores or a pore array 115 can be disposed in a location of a receiver speaker of the electronic device. In addition, any areas of the polymeric film which cover microphones or other acoustic transducers in the electronic device can also include pores. Control surfaces 125 and sealable flaps 130, 135 may be formed in the polymeric film to removably seal openings for areas such as charging ports, headphone ports, or other connections. These areas may be formed of suitable polymeric materials by insert-mold, over-mold, or alternate means to accommodate the use of buttons and ports.

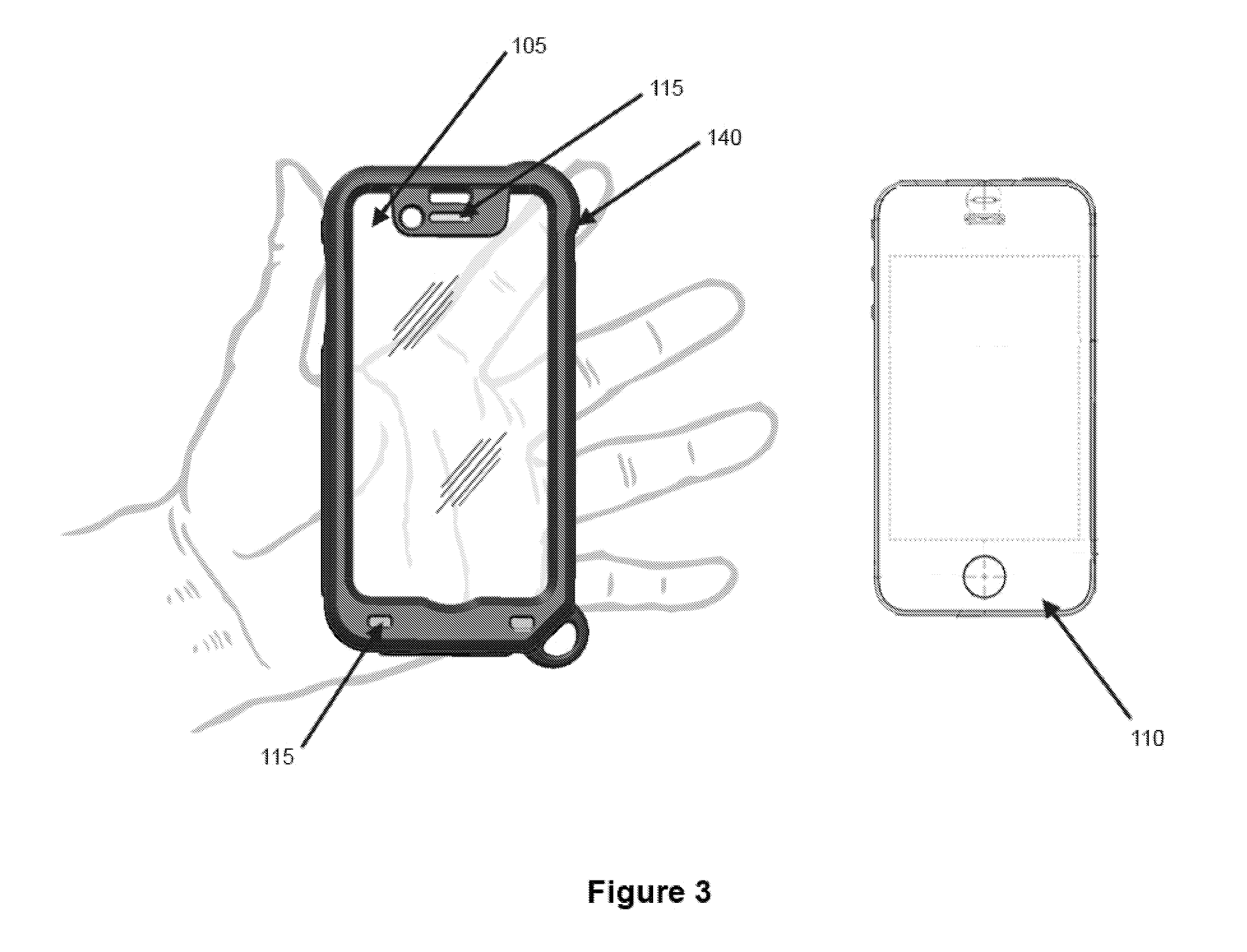

Referring to FIG. 3, in another embodiment of the present invention, the polymeric film 105 can be integrated with a cover or case 140 for the electronic device 110, where the case includes a device housing for the electronic device. Again, similar to the above embodiments, pores or a pore array 115 may be present in the polymeric film 105 to permit sound to travel through the film, where desired, while still keeping the elements, such as liquids and contaminants, from entering openings in the electronic device 110.

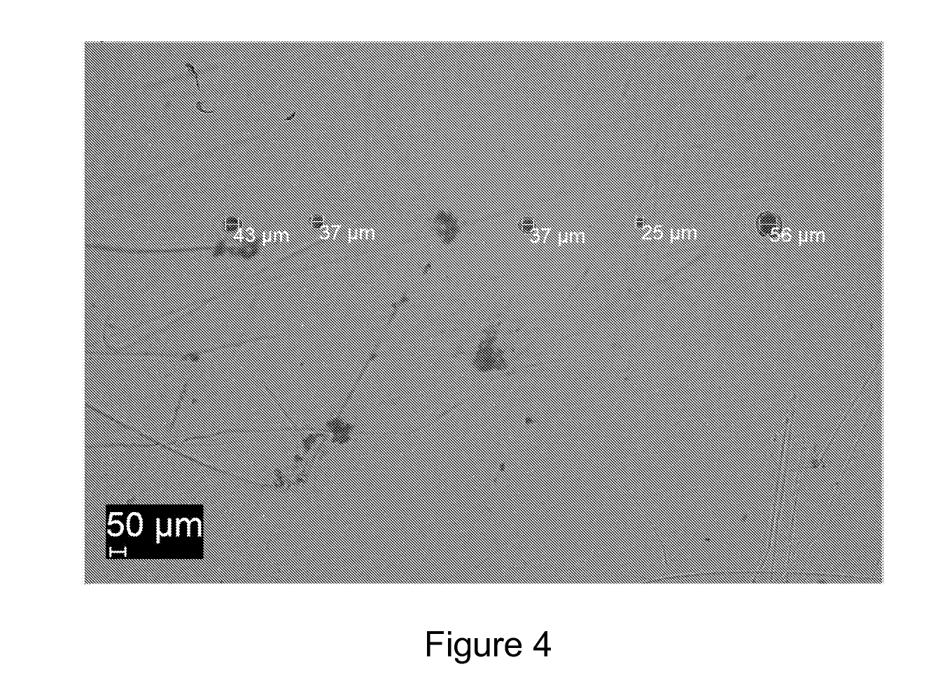

FIG. 4 is a photograph of a magnified protective film to illustrate the pores therein. FIG. 4 is provided to show that pores can be formed through the protective film substrate to a desired pore diameter. In one example, in a sample polymeric film specimen tested having a 260 micrometer thickness, the pore diameter is less than 150 micrometers. In another example with a 260 micrometer thick film sample, the range of suitable pore diameter may be from about 20 to 40 micrometers; this range has shown to be desirably efficient in restricting liquid ingress while allowing sound transmission. In another example embodiment, the pore diameter in a 260 micrometer thick polymeric film sample is in a range of 5-20 micrometers, small enough to prevent liquid ingress as well as particles smaller than liquid droplets, such as fine grain dust. Required pore diameters may be affected by material selection, material thickness, and/or the type of substance to restrict. For example, a 20 micrometer diameter pore may be sufficient for low pressure liquid ingress, but a pore size at 5 micrometers in diameter or less may be required for certain substances such as grain dust.

Interpore spacing (space between adjacent pores) and open area percentages have been evaluated as well for the pores of the protective film. In one example, interpore spacing may be in a range of 5-500 micrometers measured from center of pore to center of pore. In one example, a desirable open area percentage using a 260 micrometer thick protective polymeric film sample was found to be in a range of 10-54%. In a specific example using the 260 micrometer sample film, open area percentage was found to be in an ideal range of 15-30%. Interpore spacing requirements may also be affected by material selection, material thickness, and/or the type of substance to restrict. For example, a 60 micrometer interpore spacing may be suitable for a 35 micrometer pore diameter while maintaining mechanical stability of the substrate, but a pore diameter size less than 5 micrometers may require less interpore spacing, allowing a greater total density of pores in a given area.

It should be understood, of course, that the foregoing relates to exemplary embodiments of the invention and that modifications may be made without departing from the spirit and scope of the invention as set forth in the following claims.

What is claimed is:

1. A protective film for an electronic device comprising:
a polymeric film operable to cover at least a portion of the electronic device, and
a plurality of pores directly manufactured in, or cut in the polymeric film in locations where sound passes into or out of the electronic device, the pores adapted to allow sound transmission while restricting liquid ingress.

2. The protective film of claim 1, wherein each of the pores has a pore diameter in a range of between 1 and 1000 micrometers.

3. The protective film of claim 1, wherein each of the pores has a pore diameter of less than 150 micrometers.

4. The protective film of claim 1, wherein each of the pores has a pore diameter in a range of between 20 to 40 micrometers.

5. The protective film of claim 1, wherein each of the pores has a pore diameter in a range of between 5 to 20 micrometers.

6. The protective film of claim 1, wherein the film wraps around perimeter edges thereof so that portions of the film covers multiple sides of the electronic device.

7. The protective film of claim 1, wherein portions of the film including the pores therein are disposed at speaker and microphone locations in the electronic device.

8. A case for an electronic device, comprising:
a device housing,
a polymeric film membrane attached to the device housing and operable to cover at least a portion of the electronic device, and
a plurality of pores directly manufactured in, or cut in the polymeric film membrane in locations where sound passes into or out of the electronic device, the pores adapted to allow sound transmission while limiting liquid ingress.

9. The case of claim 8, wherein each of the pores has a pore diameter in a range of between 1 and 1000 micrometers.

10. The case of claim 8, wherein each of the pores has a pore diameter of less than 150 micrometers.

11. The case of claim 8, wherein each of the pores has a pore diameter in a range of between 20 to 40 micrometers.

12. The case of claim 8, wherein each of the pores has a pore diameter in a range of between 5 to 20 micrometers.
